(19) United States
(12) Patent Application Publication
(10) Pub. No.: US 2025/0210574 A1
(43) Pub. Date: Jun. 26, 2025

(54) SEMICONDUCTOR DEVICE, POWER DEVICE, AND POWER MODULE

(71) Applicants: Kabushiki Kaisha Toshiba, Tokyo (JP); Toshiba Electronic Devices & Storage Corporation, Tokyo (JP)

(72) Inventor: Fumiyoshi KAWASHIRO, Tokyo (JP)

(73) Assignees: Kabushiki Kaisha Toshiba, Tokyo (JP); Toshiba Electronic Devices & Storage Corporation, Tokyo (JP)

(21) Appl. No.: 19/076,058

(22) Filed: Mar. 11, 2025

Related U.S. Application Data
(63) Continuation of application No. PCT/JP2024/008127, filed on Mar. 4, 2024.

(30) Foreign Application Priority Data
Jul. 31, 2023 (JP) 2023-124492

(51) Int. Cl. H01L 23/00

(52) U.S. Cl. CPC H01L 24/29; H01L 24/32; H01L 24/40; H01L 24/48; H01L 24/73; H01L 2224/29005; H01L 2224/29084; H01L 2224/29111; H01L 2224/29139; H01L 2224/29147; H01L 2224/29155; H01L 2224/29166; H01L 2224/32245; H01L 2224/32503; H01L 2224/40245; H01L 2224/48245; H01L 2224/73263; H01L 2224/73265; H01L 2924/01028; H01L 2924/01046; H01L 2924/01047; H01L 2924/01079; H01L 2924/13055; H01L 2924/13091; H01L 2924/35121

(57) ABSTRACT

According to one embodiment, a semiconductor device includes: a semiconductor chip; and a first conductive layer provided on a side of a first surface of the semiconductor chip, wherein the first conductive layer includes an intermetallic compound layer containing copper (Cu), tin (Sn), and silver (Ag), and a concentration of the silver relative to the tin in the first conductive layer is equal to or greater than 1.0 at % and equal to or less than 7.9 at %.

### CROSS-REFERENCE TO RELATED APPLICATIONS

This application is a Continuation application of PCT Application No. PCT/JP2024/008127, filed Mar. 4, 2024 and based upon and claiming the benefit of priority from Japanese Patent Application No. 2023-124492, filed Jul. 31, 2023, the entire contents of all of which are incorporated herein by reference.

### FIELD

Embodiments described herein relate generally to a semiconductor device, a power device, and a power module.

### BACKGROUND

A power device having a structure in which a semiconductor chip is bonded to a copper member by an intermetallic compound is known.

### BRIEF DESCRIPTION OF THE DRAWINGS

FIG. 1 is a sectional view illustrating a configuration example of a semiconductor device according to an embodiment.

FIG. 2 is a diagram illustrating an experimental result of the semiconductor device of the embodiment.

FIG. 3 is a sectional view illustrating a specific example of the semiconductor device according to the embodiment.

FIG. 4 is a sectional view illustrating a specific example of the semiconductor device according to the embodiment.

FIG. 5 is a sectional view illustrating a specific example of the semiconductor device according to the embodiment.

FIG. 6 is a sectional view illustrating a specific example of the semiconductor device according to the embodiment.

FIG. 7 is a sectional view illustrating a specific example of the semiconductor device according to the embodiment.

FIG. 8 is a sectional view illustrating a specific example of the semiconductor device according to the embodiment.

FIG. 9 is a sectional view illustrating a modification of the semiconductor device according to the embodiment.

FIG. 10 is a sectional view illustrating a modification of the semiconductor device according to the embodiment.

### DETAILED DESCRIPTION

In general, according to one embodiment, a semiconductor device includes: a semiconductor chip; and a first conductive layer provided on a side of a first surface of the semiconductor chip, wherein the first conductive layer includes an intermetallic compound layer containing copper (Cu), tin (Sn), and silver (Ag), and a concentration of the silver relative to the tin in the first conductive layer is equal to or greater than 1.0 at % and equal to or less than 7.9 at %.

Hereinafter, an embodiment will be described with reference to the drawings. In the following description, elements having the same function and configuration are denoted by the same reference numeral. Further, in the following embodiment, in a case where components (for example, circuits, wirings, various voltages and signals, and the like) having reference numeral with numbers/letters for distinction at the end are not necessarily distinguished from each other, a description (reference numeral) in which the numbers/letters at the end are omitted is used. Dimensions and ratios in the drawings are not necessarily the same as actual ones.

### Embodiment

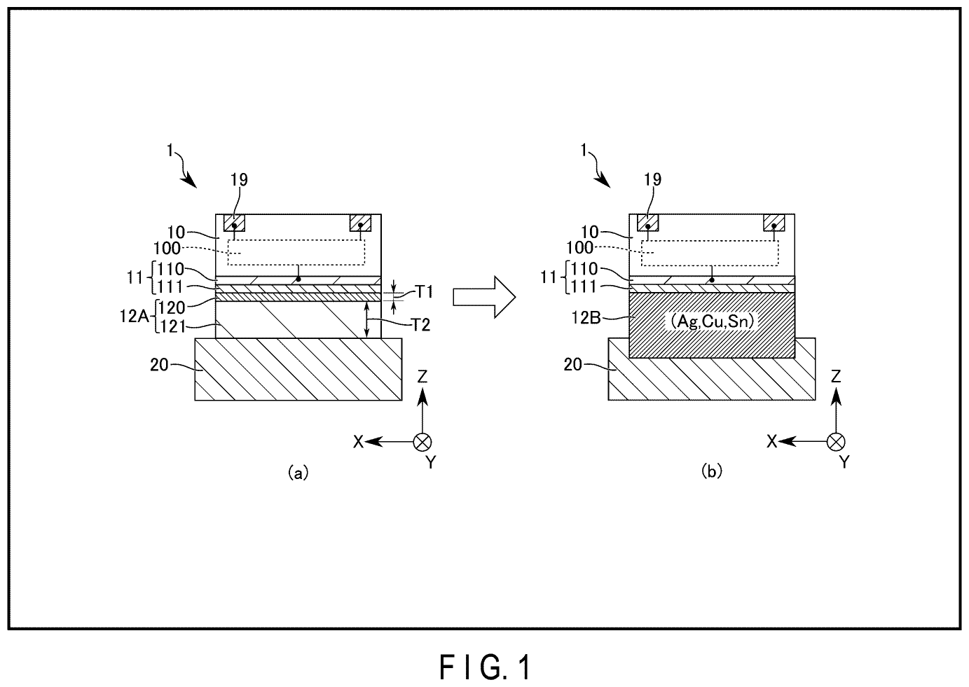

A semiconductor device according to an embodiment will be described with reference to FIGS. 1 to 10.

### (1) Basic Example

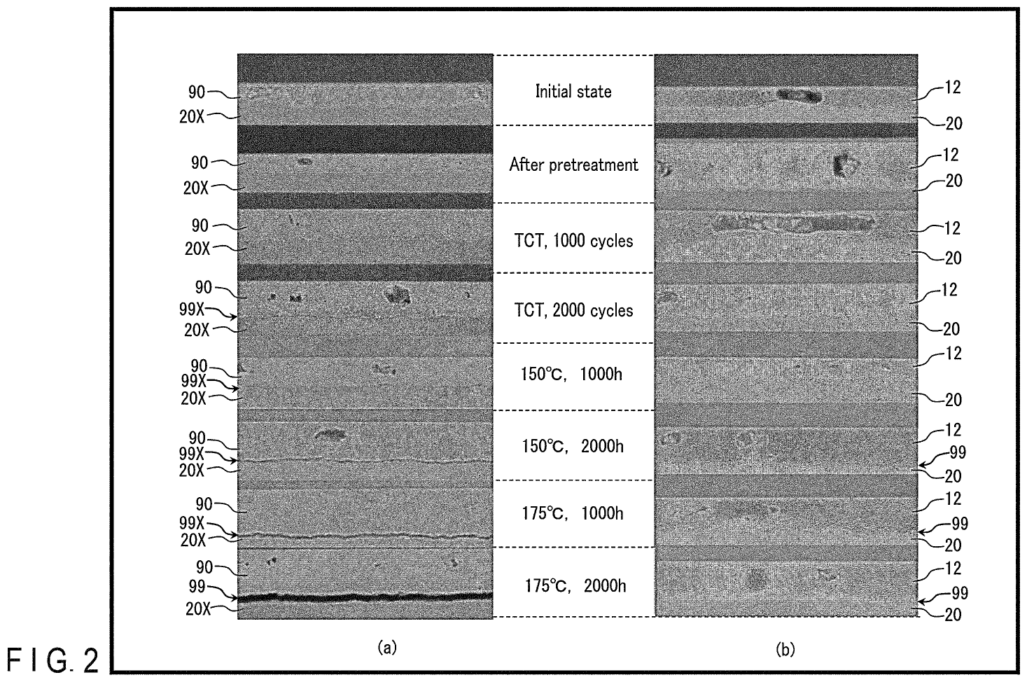

A basic example of the semiconductor device according to the embodiment will be described with reference to FIGS. 1 and 2.

### (Configuration)

FIG. 1 is a sectional view for explanation of a structure of a basic example of the semiconductor device according to the present embodiment.

A portion (a) in FIG. 1 is a sectional view illustrating a state before the semiconductor device according to the present embodiment is bonded to a copper base material. A portion (b) in FIG. 1 is a sectional view illustrating a state after the semiconductor device according to the present embodiment is bonded to a copper base material.

As illustrated in FIG. 1, a semiconductor device 1 of the embodiment is provided on a copper layer (Cu layer) 20 which is the copper base material. The semiconductor device 1 includes a semiconductor chip 10, a conductive layer 11, a conductive layer 12 (12A, 12B), and a pad (electrode) 19.

The semiconductor chip 10 has a cuboid or rectangular parallelepiped structure. The semiconductor chip 10 has a front surface (upper surface) and a back surface (lower surface) extending in an X-Y plane.

The semiconductor chip 10 includes a silicon substrate (Si substrate) or a silicon carbide substrate (SiC substrate).

The semiconductor chip 10 is a chip of a vertical power device. An output current of the vertical power device flows between the front surface and the back surface of the semiconductor chip 10. The semiconductor chip 10 includes an element portion 100. The element portion 100 includes a semiconductor element such as a MOS field effect transistor, an insulated gate bipolar transistor (IGBT), or a diode.

Note that a chip of a lateral power device may be used for the semiconductor chip 10. In this case, no current flows to a side of the copper base material, and the copper base material serves as a heat sink.

For example, the power device provided in the semiconductor chip 10 is an Si device having a breakdown voltage from 20 V to 200 V or an SiC device having a breakdown voltage from 600 V to 4500 V.

The pad 19 is provided on the front surface of the semiconductor chip 10. The pad 19 is electrically connected to the element portion 100 via a contact portion (not illustrated) and interconnect (not illustrated) in the semiconductor chip 10.

The conductive layer 11 and the conductive layer 12 are provided on a side of the back surface of the semiconductor chip 10 in the Z direction.

The conductive layer 11 is provided between the semiconductor chip 10 and the conductive layer 12. The conductive layer 11 is provided under the back surface of the semiconductor chip 10. The conductive layer 11 is electrically connected to the element portion 100. The conductive layer 11 includes two metal layers 110, 111 stacked in the Z direction.

The metal layer 110 is in contact with the back surface of the semiconductor chip 10. The metal layer 110 is provided for improving bonding between the semiconductor chip 10 and the conductive layer 12 and improving electrical characteristics between the semiconductor chip 10 and the conductive layer 12. The metal layer 110 is, for example, a titanium layer (Ti layer).

The metal layer 111 is provided between the metal layer 110 and the conductive layer 12. The metal layer 111 functions as a barrier metal that prevents a chemical reaction between the conductive layer 12 and the metal layer (Ti layer) 110 and diffusion of constituent members (atoms) between the conductive layer 12 and the metal layer 110. The metal layer 111 is, for example, a nickel layer (Ni layer).

Hereinafter, the conductive layer 11 is also referred to as a back metal layer 11.

The conductive layer 12 is provided between the back metal layer 11 and the Cu layer 20. The conductive layer 12 is in contact with the Cu layer 20.

As illustrated in the portion (a) in FIG. 1, in a state before the semiconductor device 1 is bonded to the Cu layer 20, the conductive layer 12A includes metal layers 120, 121 stacked in the Z direction.

The metal layer 120 is in contact with the back metal layer 11. The metal layer 120 is, for example, a silver layer (Ag layer).

The metal layer 121 is provided between the metal layer (Ag layer) 120 and the Cu layer 20. For example, the metal layer 121 is a tin layer (Sn layer).

The Ag layer 120 has a film thickness T1. The Sn layer 121 has a film thickness T2. The film thickness T1 is thinner than the film thickness T2. For example, when an area of the front surface (and the back surface) of the semiconductor chip 10 is 0.8 mm×0.8 mm, the film thickness T2 of the Sn layer 121 is set to about 5.0 μm. When the film thickness T2 of the Sn layer 121 is 5.0 μm, the film thickness T1 of the Ag layer 120 is, for example, equal to or greater than 30 nm and equal to or less than 100 nm. In this case, the film thickness T1 of the Ag layer 120 is preferably set to, for example, about 60 nm.

For example, the Ag layer 120 is formed on the Ni layer 111 of the back metal layer 11 by a vacuum evaporation method or a sputtering method.

For example, the Sn layer 121 is a metal paste. The Sn layer 121 may be formed on the Ag layer 120 by a vacuum evaporation method or a sputtering method.

The semiconductor device 1 in the portion (a) in FIG. 1 is, for example, a bare chip.

As illustrated in the portion (b) in FIG. 1, the conductive layer 12B is an intermetallic compound layer in a state after the semiconductor device 1 is bonded to the Cu layer 20. The conductive layer 12B is, for example, a layer formed by transient liquid phase sintering (TLPS) bonding between a member constituting the conductive layer 12A and the Cu layer.

In order to bond the semiconductor device 1 to the Cu layer 20, a heat treatment for TLPS is applied to the semiconductor device 1 and the Cu layer 20. The Ag layer 120, the Sn layer 121, and the Cu layer 20 in the portion (a) in FIG. 1 are bonded by a chemical reaction due to the heat treatment. For example, the conductive layer 12B after the heat treatment contains (includes) a metal compound of Ag, Cu, and Sn.

In the present embodiment, the conductive layer 12B is a CuSn layer to which Ag is added. The conductive layer 12B is also referred to as an AgCuSn layer.

The conductive layer 12B and the Cu layer 20 are integrated by intermetallic bonding due to a heat treatment. For example, the conductive layer 12B is continuous with the Cu layer 20.

Hereinafter, the conductive layer 12 (12A, 12B) is also referred to as a mount layer 12.

A film thickness of the AgCuSn layer 12B is equal to or greater than 3 μm and equal to or less than 50 μm. For example, the film thickness of the AgCuSn layer 12B is desirably equal to or greater than 5 μm and equal to or less than 15 μm. When the film thickness of the AgCuSn layer 12B is equal to or greater than 5 μm and equal to or less than 15 μm, it is possible to further ensure heat dissipation of the semiconductor device 1 and reliability of bonding between the mount layer 12 and the Cu layer 20.

It is preferable that when the AgCuSn layer 12B is formed, a heat treatment at a temperature equal to or higher than the melting point of Sn is applied to the conductive layer (Ag/Sn layer) 12A and the Cu layer 20. This promotes diffusion of Ag, Sn, and Cn between the conductive layer 12A and the Cu layer 20. As a result, the mount layer 12 and the Cu layer 20 of the semiconductor device 1 can be integrated by formation of the intermetallic compound.

For example, in the present embodiment, the conductive layer 12B containing (including) a CuSn intermetallic compound to which Ag is added as the mount layer 12 is a layer made of a hypoeutectic of AgSn and CuSn. For example, the AgCuSn layer 12B contains at least one of Ag₃Sn and AgsSn. For example, the AgCuSn layer 12B contains at least one of Cu₃Sn, Cu₆Sn₅, and Cu—Sn₂.

In the present embodiment, in the conductive layer 12B made of a CuSn metal compound containing Ag, a concentration of Ag with respect to Sn is equal to or greater than 1.0 at % (atomic percent) and equal to or less than 7.9 at %. For example, the concentration of Ag with respect to Sn is preferably lower than 7.9 at %.

For example, in the present embodiment, the AgCuSn layer 12B can realize a thermal conductivity of equal to or greater than 34 W/mK.

For example, the AgCuSn layer 12B may further include Ni. Note that the AgCuSn layer 12B as the mount layer 12 may contain another element as long as a concentration of the element is a trace amount equal to or less than a eutectic point of AgCuSn.

The Ag layer may remain between the AgCuSn layer 12B and the Ni layer 111.

With the above configuration, it is possible to improve reliability of the semiconductor device 1 of the present embodiment.

### (Production Method)

A method for manufacturing the semiconductor device of the present embodiment will be described with reference to FIG. 1.

As illustrated in the portion (a) in FIG. 1, the element portion 100 including a semiconductor element such as a MOSFET or an IGBT is formed on a semiconductor substrate (for example, an Si substrate or an SiC substrate). Thereafter, the pad 19 is formed on a side of the front surface of the semiconductor substrate. Thus, the semiconductor chip 10 is formed.

The back metal layer 11 configured by a stacked body of the Ti layer 110 and the Ni layer 111 is formed on the back surface of the semiconductor chip 10 by a sputtering method or a vacuum evaporation method.

On the side of the back surface of the semiconductor chip 10, the Ag layer 120 is formed on the Ni layer 111 of the back metal layer 11 by a sputtering method or a vacuum evaporation method. The Ag layer 120 has a film thickness of, for example, 60 nm.

The Sn layer 121 is formed on the Ag layer 120 by applying a metal paste, by a sputtering method, or by a vacuum evaporation method. The Sn layer 121 has a film thickness of, for example, 5 μm.

As a result, the mount layer 12 configured by a stacked body of the Ag layer 120 and the Sn layer 121 is formed on the back metal layer 11 on the side of the back surface of the semiconductor chip 10.

Through the above steps, a bare chip of the semiconductor device 1 is formed.

The bare chip of the semiconductor device 1 is mounted on the Cu layer 20 such that the Sn layer 121 of the mount layer 12 is in contact with the Cu layer (Cu base material) 20.

In a state where the Sn layer 121 is in contact with the Cu layer 20, a heat treatment for bonding the semiconductor device 1 and the Cu layer 20 (hereinafter, also referred to as mount bonding processing) is performed at the temperature equal to or higher than the melting point of Sn.

By the heat treatment, diffusion of Ag, Sn, and Cu as constituent elements occurs between the mount layer 12 and the Cu layer 20.

As a result, as illustrated in the portion (b) in FIG. 1, the intermetallic compound layer 12B containing Ag, Cu, and Sn is formed between the semiconductor device 1 and the Cu layer 20. The AgCuSn layer 12B, which is an intermetallic compound layer, is partially integrated with the Cu layer 20. The AgCuSn layer 12B and the Cu layer 20 form a continuous layer (region) in which no crack occurs at the interface.

The semiconductor device 1 (semiconductor chip 10) is bonded to the Cu layer 20 with the AgCuSn layer 12B interposed therebetween.

Through the above steps, the semiconductor device 1 according to the present embodiment is completed.

### Experiment

Characteristics of the semiconductor device according to the present embodiment will be described with reference to FIG. 2.

FIG. 2 illustrates a sectional image when various heat treatments are applied to the semiconductor device of the present embodiment and a semiconductor device of a comparative example.

A portion (a) in FIG. 2 is a sectional image in the vicinity of a boundary between a mount layer and a Cu layer of the semiconductor device of the comparative example. The semiconductor device of the comparative example includes a CuSn-based metal compound layer, in the mount layer, to which Ag is not added.

A portion (b) in FIG. 2 is a sectional image in the vicinity of a boundary between the mount layer and the Cu layer of the semiconductor device of the present embodiment.

In each of the portions (a) and (b) in FIG. 2, sectional images of the mount layer of an experimental sample in an initial state, an experimental sample after a pretreatment, an experimental sample after a thermal cycle test, and an experimental sample after a high temperature exposure treatment are shown.

In the experimental samples of the comparative example and the present embodiment, the film thickness of the Sn layer of the mount layer is set to 5.0 μm in a state before the mount layer is bonded to the Cu layer. In the experimental samples of the present embodiment, the film thickness of the Ag layer of the mount layer is set to 60 nm in a state before the mount layer is bonded to the Cu layer. In the experimental samples of the present embodiment, the concentration of Ag with respect to Sn in the mount layer is 1.9 at %.

In the experimental samples of the semiconductor device of the comparative example, a conductive layer 90 not containing Ag is bonded to the Cu layer at a mount temperature of 380 degrees Celsius. In the experimental samples of the semiconductor device of the present embodiment, the conductive layer 12B containing Ag is bonded to the Cu layer at a mount temperature of 380 degrees Celsius.

The pretreatment performed on the experimental samples of the semiconductor devices of the comparative example and the present embodiment is a treatment related to a moisture sensitivity level (MSL).

A thermal cycle test (TCT) of 1000 cycles and a thermal cycle test of 2000 cycles are applied on the experimental samples of the semiconductor devices of the comparative example and the present embodiment, respectively.

As the high temperature exposure treatment, a heat treatment at 150 degrees Celsius for 1000 hours, a heat treatment at 150 degrees Celsius for 2000 hours, a heat treatment at 175 degrees Celsius for 1000 hours, and a heat treatment at 175 degrees Celsius for 2000 hours are applied to the experimental samples of the semiconductor devices of the comparative example and the present embodiment, respectively.

As shown in the portion (a) in FIG. 2, in the semiconductor device of the comparative example, a mount layer (hereinafter, referred to as a CuSn layer) 90 made of a CuSn intermetallic compound is formed in the initial state after bonding to a Cu layer 20X. The CuSn layer 90 is integrated with the Cu layer 20X.

For example, in the semiconductor device of the comparative example, in a thermal cycle test of 2000 cycles, a Kirkendall void 99X is generated between the CuSn layer 90 and the Cu layer 20X.

When the semiconductor device of the comparative example is subjected to the high temperature exposure treatment at 150 degrees Celsius, the Kirkendall void 99X is generated between the CuSn layer 90 and the Cu layer 20X. In the comparative example, the Kirkendall void 99X obtained by the heat treatment under a condition at 150 degrees Celsius for 2000 hours is larger than a Kirkendall void 99X obtained by the heat treatment under a condition at 150 degrees Celsius for 1000 hours.

When the semiconductor device of the comparative example is subjected to the high temperature exposure treatment at 175 degrees Celsius, the Kirkendall void 99X is generated between the CuSn layer 90 and the Cu layer 20X. The Kirkendall void 99X obtained by the heat treatment under a condition at 175 degrees Celsius for 2000 hours is larger than the Kirkendall void 99X obtained by the heat treatment under a condition at 175 degrees Celsius for 1000 hours. In addition, the Kirkendall void 99X generated by the heat treatment at 175 degrees Celsius is larger than the Kirkendall void 99X generated by the heat treatment at 150 degrees Celsius.

As described above, when the semiconductor device of the comparative example is left in a high temperature state of equal to or higher than 150 degrees Celsius, a relatively large Kirkendall void is generated between the CuSn layer 90 and the Cu layer 20X.

Therefore, when Ag is not added to the mount layer 90 made of a CuSn-based intermetallic compound as in the comparative example, cracks (for example, voids) are generated between the mount layer 90 and the Cu layer 20X. Therefore, in the semiconductor device of the comparative example, the bonding strength between the semiconductor chip and the Cu base material is deteriorated.

As shown in the portion (b) in FIG. 2, in the semiconductor device 1 of the present embodiment, the mount layer (AgCuSn layer) 12B made of a CuSn intermetallic compound to which Ag is added is formed in the initial state after bonding. The AgCuSn layer 12B is integrated with the Cu layer 20.

When the thermal cycle test is performed on the semiconductor device 1 of the present embodiment, a Kirkendall void does not occur between the mount layer 12B and the Cu layer 20.

Even when the heat treatment (high temperature exposure treatment) under the condition at 150 degrees Celsius for 1000 hours is performed on the semiconductor device 1 of the present embodiment, a Kirkendall void is not generated between the mount layer 12B and the Cu layer 20.

When the heat treatment under the condition at 150 degrees Celsius for 2000 hours is performed on the semiconductor device 1 of the present embodiment, a Kirkendall void 99 is generated between the mount layer 12B and the Cu layer 20.

Further, the Kirkendall void 99 is generated between the mount layer 12B and the Cu layer 20 in both cases where the heat treatment at 175 degrees Celsius for 1000 hours is performed and the heat treatment at 175 degrees Celsius for 2000 hours is performed on the semiconductor device 1 of the present embodiment.

However, for the heat treatment under the same condition, a size of the Kirkendall void generated in the semiconductor device 1 of the embodiment is smaller than a size of the Kirkendall void generated in the semiconductor device of the comparative example.

When the semiconductor device bonded to the Cu layer is left at a high temperature, Cu is supplied from the Cu layer to the mount layer. As a result, Cu is bonded to Sn in the mount layer, and CuSn is formed. According to the amount of Cu diffused from the Cu layer to the mount layer, a Kirkendall void is generated between the Cu layer and the mount layer.

In a case where Ag is added to the mount layer 12 as in the present embodiment, a consumption amount of Cu (diffusion of Cu) during formation of the intermetallic compound is reduced as compared with the case where the metal layer serving as the base of the mount layer is composed of only Sn.

As a result, as in the experimental sample illustrated in the portion (b) in FIG. 2, in the semiconductor device 1 of the present embodiment, a Kirkendall void is hardly generated.

### Summary

As in the semiconductor device 1 of the present embodiment, by adding Ag to the CuSn intermetallic compound layer, a size of a Kirkendall void generated between the mount layer and the Cu layer in the high temperature exposure is reduced.

Therefore, with the semiconductor device 1 of the present embodiment, it is possible to suppress an occurrence of cracks at the boundary between the mount layer and the Cu layer. Thus, with the semiconductor device 1 of the present embodiment, it is possible to improve bonding strength between the mount layer and the Cu layer.

As a result, with the semiconductor device 1 of the present embodiment, it is possible to reduce bonding failure between the semiconductor device and the Cu layer.

In the present embodiment, the AgCuSn layer 12B as the mount layer includes an AgSn phase and a CuSn phase. The Young's modulus of AgSn is lower than the Young's modulus of CuSn.

As a result, in the semiconductor device 1 of the present embodiment, a stress resistance of the mount layer is improved.

Therefore, with the semiconductor device 1 of the present embodiment, it is possible to prevent peeling (or breakage) occurring between the semiconductor chip and the base layer made of Cu.

In the semiconductor device 1 of the present embodiment, the intermetallic compound based on CuSn is used for bonding the semiconductor device and a Cu material. As a result, the semiconductor device 1 of the present embodiment can ensure high heat resistance having a melting point equal to or higher than 400 degrees Celsius. In addition, with the semiconductor device 1 of the present embodiment, it is possible to reduce the cost of the mount layer bonded to the Cu layer. In the semiconductor device 1 of the present embodiment, the semiconductor device and the Cu material can be bonded without lead (Pb).

In the semiconductor device 1 of the present embodiment, the film thickness of the mount layer of AgCuSn is controlled from 5 μm to 15 μm. As a result, it is possible to improve heat dissipation of the semiconductor device 1 of the present embodiment. In addition, by thinning the mount layer, it is possible to reduce the thermal resistance of the semiconductor device 1 of the present embodiment.

As described above, it is possible to improve reliability of the semiconductor device 1 of the present embodiment.

### (2) Specific Examples

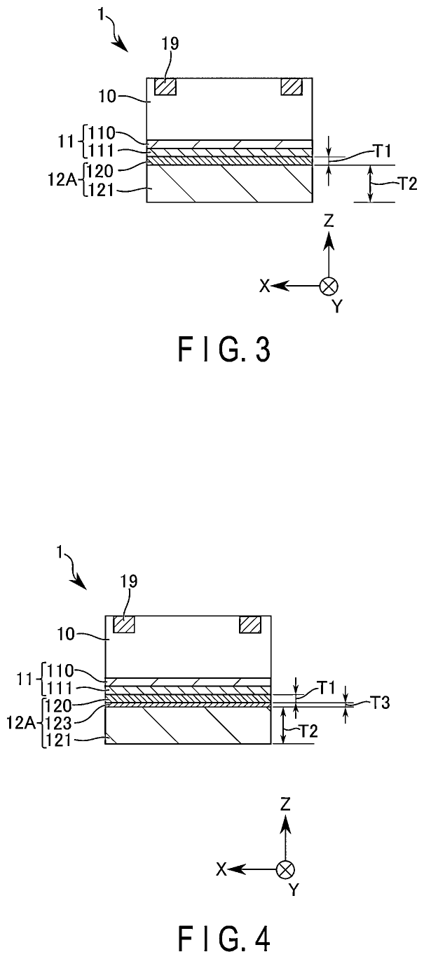

A specific example (application) of the semiconductor device of the present embodiment will be described with reference to FIGS. 3 to 8.

FIG. 3 is a sectional view illustrating one specific example of the semiconductor device according to the present embodiment.

Before the semiconductor device 1 of the present embodiment is mounted on a package, the semiconductor device 1 is provided in a state before the mount layer 12 is formed a metal compound with Cu.

In this case, the semiconductor device 1 of the embodiment includes the mount layer 12A including the Ag layer 120 and the Sn layer 121. The mount layer 12A is a stacked body (Ag/Sn layer) of the Ag layer 120 and the Sn layer 121. The Ag layer 120 is in contact with the Ni layer 111 of the back metal layer 11. The Ag layer 120 is provided between the Ni layer 111 and the Sn layer 121. One surface of the Sn layer 121 is in contact with the Ag layer 120. A surface opposing the one surface of the Sn layer 121 is exposed.

The Ag layer 120 may be provided in the Sn layer 121. In this case, the Ag layer 120 is sandwiched between two portions (Sn portions) in the Sn layer 121. The Sn layer 121 may be provided between the Ag layer 120 and the Ni layer 111.

The Ag layer 120 is formed by a film formation technique such as a vacuum evaporation method or a sputtering method.

The Sn layer 121 may be a layer formed from a metal paste or a layer formed by a film formation technique.

The film thickness T1 of the Ag layer 120 is thinner than the film thickness T2 of the Sn layer 121. It is desirable that the film thickness T1 of the Ag layer 120 and the film thickness T2 of the Sn layer 121 are set such that a concentration of Ag with respect to Sn is equal to or greater than 1.0 at % and equal to or less than 7.9 at %. For example, when the film thickness T2 of the Sn layer 121 is 5.0 μm, the film thickness T1 of the Ag layer 120 is 60 nm.

FIG. 4 is a sectional view illustrating one specific example of the semiconductor device of the present embodiment.

As illustrated in FIG. 4, in the mount layer 12A, a metal layer 123 may be provided between the Ag layer 120 and the Sn layer 121.

The metal layer 123 is a layer containing at least one of gold (Au), palladium (Pd), and Ni.

The metal layer 123 is one of an Au layer, a Pd layer, or an Ni layer. The metal layer 123 may be a stacked film containing two or more selected from Au, Pd, and Ni, or may be an intermetallic compound layer containing two or more selected from Au, Pd, and Ni.

A film thickness T3 of the metal layer 123 is equal to or less than the film thickness T1 of the Ag layer 120.

At the time of bonding between the mount layer 12A and the Cu layer, the metal layer 123 is melted by heat, and constituent elements of the metal layer 123 are diffused and added into the CuSn layer together with Ag.

As a result, the mount layer 12B in the portion (b) in FIG. 1 contains elements other than Ag, Cu, and Sn in the AgCuSn layer.

Note that at least one of the Ag layer 120 and the Sn layer 121 may contain at least one of Au, Pd, and Ni. The metal layer 123 may be provided between the back metal layer 11 and the Ag layer 120. The Sn layer 121 may be provided between the Ag layer 120 and the metal layer 123.

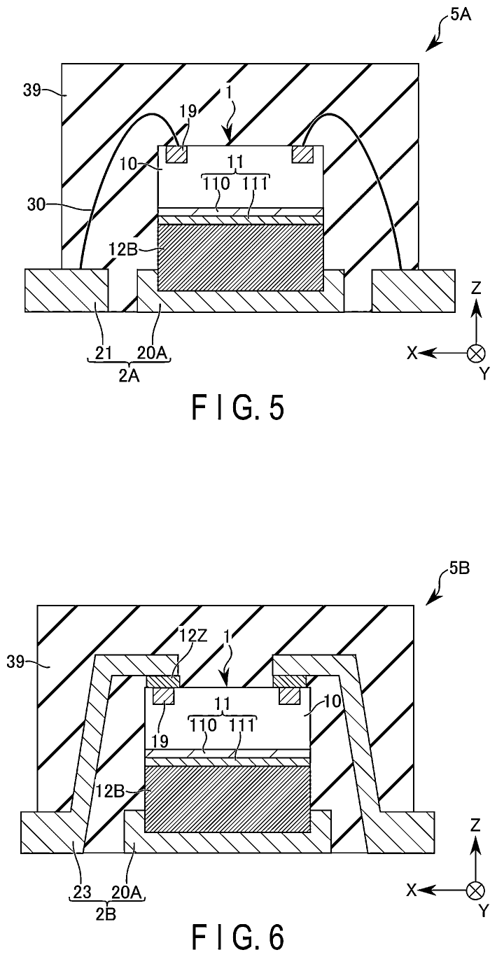

FIG. 5 is a sectional view illustrating one specific example of the semiconductor device of the present embodiment.

As illustrated in FIG. 5, the semiconductor device 1 of the present embodiment can be provided as a packaged power device 5A.

For example, the semiconductor device 1 is mounted on a lead frame 2A.

The lead frame 2A includes a mount portion (die mount portion) 20A and a plurality of lead portions (connection terminals) 21. The mount portion 20A and the lead portions 21 are Cu layers.

The semiconductor device 1 is provided on the mount portion (Cu layer) 20A.

The pad 19 is electrically connected to the lead portions 21 via a bonding wire 30.

The semiconductor device 1 mounted on the lead frame 2A is sealed by a sealing material (insulator) 39. The semiconductor device 1 is covered with the sealing material 39.

When the semiconductor device 1 is mounted on the lead frame 2, the mount layer of the semiconductor device 1 is bonded to the mount portion 20A of the lead frame 2A by a heat treatment. By bonding the conductive layer including the Ag layer and the Sn layer to the mount portion 20A, the mount layer 12B including the AgCuSn layer is formed on the side of the back surface of the semiconductor chip 10. The AgCuSn layer 12B as the mount layer is integrated with the mount portion 20A made of Cu.

The semiconductor device 1 is bonded to the lead frame 2A by the AgCuSn layer 12B.

FIG. 6 is a sectional view illustrating one specific example of the semiconductor device of the present embodiment.

As illustrated in FIG. 6, in a power device 5B, a conductive layer 12Z made of AgCuSn may be provided on a side of the front surface of the semiconductor chip 10.

The lead frame 2B includes a lead portion (connection terminal) 23. The lead portion 23 is a Cu layer. The lead portion 23 extends from a bottom surface of the sealing material 39 to the upper surface (front surface) of the semiconductor chip 10. One end of the lead portion 23 is adjacent to the mount portion 20A. The other end of the lead portion 23 is provided above the pad 19 via the conductive layer 12Z.

At the time of manufacturing the semiconductor device 1, a conductive layer including an Ag layer and an Sn layer, for example, is provided on the pad 19. On the side of the front surface of the semiconductor chip 10, the Ag layer is provided between the Sn layer and the pad 19.

When the semiconductor device 1 is mounted on the lead frame 2, the semiconductor device 1 is mounted on the mount portion 20A, and the other end of the lead portion 23 is provided on the conductive layer (Sn/Ag layer) on the upper surface of the semiconductor chip 10.

By the heat treatment, the AgCuSn layer 12B is formed between the semiconductor chip 10 and the mount portion 20A, and the AgCuSn layer 12Z is formed between the pad 19 and the lead portion 23.

As a result, the AgCuSn layer 12Z is bonded to the lead portion 23 of the Cu layer on the side of the front surface of the semiconductor chip 10. The AgCuSn layer 12Z is integrated with the Cu layer of the lead portion 23. Note that the AgCuSn layer 12Z may be integrated with the pad 19 by thermal bonding between the AgCuSn layer 12Z and the pad 19.

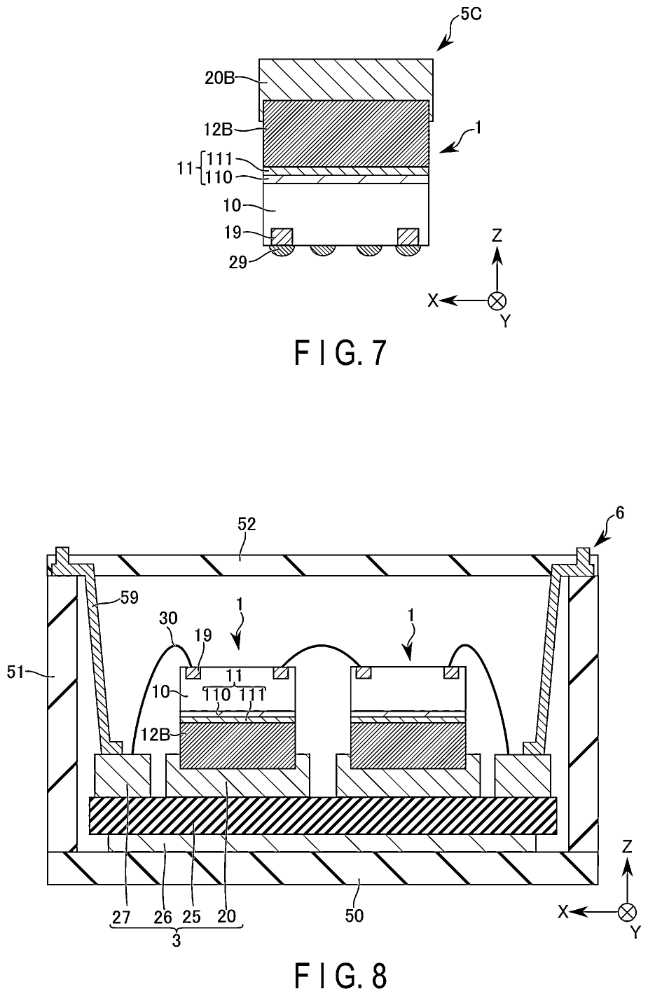

FIG. 7 is a sectional view illustrating one specific example of the semiconductor device of the present embodiment.

As illustrated in FIG. 7, a power device 5C including the semiconductor device 1 of the present embodiment may be provided without being sealed with a sealing material.

An external connection terminal 29 is connected to the pad 19 on the side of the front surface of the semiconductor chip 10. The external connection terminal 29 is a conductor containing Sn. The external connection terminal 29 is, for example, a solder ball or a bump.

A Cu layer 20B is provided on the side of the back surface of the semiconductor chip 10. The Cu layer 20B is connected to the mount layer 12B. The mount layer 12B is an AgCuSn layer. The AgCuSn layer 12B is integrated with the Cu layer 20B.

For example, the Cu layer 20B functions as an electrode and a heat sink of the power device 5C. The power device 5C in FIG. 7 may be a horizontal power device. When the power device 5C is a horizontal power device, no current flows to a side of the Cu layer 20B, and the Cu layer 20B functions as a heat sink.

FIG. 8 is a sectional view illustrating one specific example of the semiconductor device of the present embodiment.

As illustrated in FIG. 8, the semiconductor device 1 of the present embodiment may be used for a power module 6.

The power module 6 is, for example, a DC-DC converter, an inverter, or a switch.

In the power module 6, a plurality of the semiconductor devices 1 of the embodiment are provided on a circuit board 3.

The circuit board 3 on which the semiconductor devices 1 are mounted is provided on a base substrate 50.

A case 51 is provided on the base substrate 50 so as to surround the circuit board 3. For example, an insulator (not illustrated) is provided in a space surrounded by the case 51 on the base substrate 50. The semiconductor devices 1 in the case 51 are sealed by the insulator.

A lid 52 is provided on the case 51. The lid 52 covers the semiconductor devices 1 and the circuit board 3 from above.

An external connection terminal 59 is provided in the case 51. The external connection terminal 59 extends from a side of the case 51 toward the circuit board 3. One end of the external connection terminal 59 is connected to a wiring 27 (or the Cu layer 20) of the circuit board 3. The other end of the external connection terminal 59 protrudes from the lid 52, for example. The other end of the external connection terminal 59 is connected to an apparatus (for example, a control apparatus) outside the power module 6.

The circuit board 3 includes a metal plate 26, a ceramic plate 25, the Cu layer 20, and the wiring 27.

The metal plate 26 is a Cu plate. The metal plate 26 functions as a heat sink. The ceramic plate 25 is provided on the metal plate 26. The ceramic plate 25 electrically separates the metal plate 26 from the Cu layer 20 and the wiring 27. The ceramic plate 25 functions as a heat sink.

The Cu layer 20 and the wiring 27 are provided on the ceramic plate 25.

The semiconductor device 1 is provided on the Cu layer 20. The semiconductor device 1 is bonded to the Cu layer 20 via a mount layer (intermetallic compound layer) 12B made of AgCuSn. The AgCuSn layer 12B is integrated with the Cu layer 20. For example, the Cu layer 20 may be used as wiring.

The wiring 27 electrically connects the plurality of semiconductor devices 1 to each other. The wiring 27 is connected to the semiconductor device 1 via the bonding wire 30. The plurality of semiconductor devices 1 on the circuit board 3 are connected to each other via bonding wires 30. The wiring 27 connects the plurality of semiconductor devices 1 to the external connection terminal 59.

An output current (or output voltage) of the semiconductor device 1 is output to outside of the power module 6 via the bonding wire 30, the wiring 27, and the external connection terminal 59.

As illustrated in FIGS. 3 to 8, the semiconductor device 1 of the present embodiment is applicable to an apparatus including a Cu member. The semiconductor device 1 of the present embodiment is bonded to the Cu member via the mount layer 12B containing AgCuSn.

Therefore, it is possible to improve reliability of the apparatus including the semiconductor device 1 of the present embodiment.

### (3) Modifications

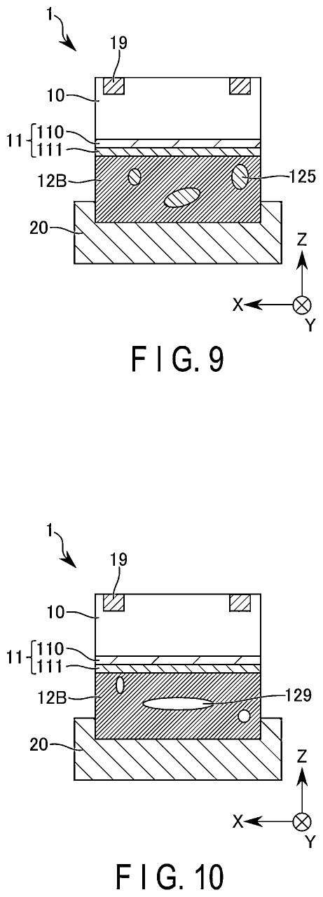

Modifications of the semiconductor device of the present embodiment will be described with reference to FIGS. 9 and 10.

FIG. 9 is a sectional view illustrating an example of the modification of the semiconductor device according to the embodiment.

As shown in FIG. 9, an Sn grains (Sn crystal) 125 may be provided in the AgCuSn layer 12B as the mount layer. For example, the Sn grain 125 is randomly disposed in the AgCuSn layer 12B.

FIG. 10 is a sectional view illustrating an example of a modification of the semiconductor device of the present embodiment.

As illustrated in FIG. 10, a gap 129 may be provided in the AgCuSn layer 12B as the mount layer. For example, the gap 129 is formed at a random position, or formed according to a position to which a pin is applied at the time of heating.

Even when the Sn grain 125 or the gap 129 is provided in the mount layer 12B as shown in FIGS. 9 and 10, the semiconductor device of the modifications of the present embodiment can obtain the above-described effects.

### (4) Others

In the above-described embodiment, a structure in which a CuSn layer to which Ag is added is used for a power device or a power module is exemplified. However, the CuSn layer to which Ag is added may be used for a semiconductor device other than a power device, such as an analog circuit and a logic circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip; and
a first conductive layer provided on a side of a first surface of the semiconductor chip, wherein
the first conductive layer includes an intermetallic compound layer containing copper (Cu), tin (Sn), and silver (Ag), and
a concentration of the silver relative to the tin in the first conductive layer is equal to or greater than 1.0 at % and equal to or less than 7.9 at %.

2. The semiconductor device according to claim 1, wherein
the first conductive layer is provided between the semiconductor chip and a copper layer.

3. The semiconductor device according to claim 1, wherein
the first conductive layer further contains at least one or more of nickel (Ni), gold (Au), and palladium (Pd).

4. The semiconductor device according to claim 1, further comprising:
a second conductive layer provided between the semiconductor chip and the first conductive layer, wherein
the second conductive layer includes a nickel layer and a titanium layer between the nickel layer and the semiconductor chip.

5. The semiconductor device according to claim 1, wherein
the first conductive layer includes an AgSn phase and a CuSn phase.

6. The semiconductor device according to claim 5, wherein
the AgSn phase contains at least one of Ag₃Sn and AgsSn, and
the CuSn phase contains at least one of Cu₃Sn, Cu₆Sn₅, and Cu₇Sn₂.

7. A power device comprising:
the semiconductor device according to claim 1; and
a lead frame including: a mount portion bonded to the semiconductor device with the first conductive layer interposed therebetween; and a terminal connected to a pad provided on a second surface of the semiconductor device, the second surface opposing the first surface, wherein
each of the mount portion and the terminal contains copper.

8. The power device according to claim 7, wherein
the semiconductor device further comprises a third conductive layer provided between the pad and the terminal,
the third conductive layer includes an intermetallic compound layer containing copper, tin, and silver, and
a concentration of the silver relative to the tin in the third conductive layer is equal to or greater than 1.0 at % and equal to or less than 7.9 at %.

9. A power module comprising:
the semiconductor device according to claim 1; and
a circuit board including a copper layer bonded to the semiconductor device with the first conductive layer interposed therebetween.

10. A semiconductor device comprising:
a semiconductor chip; and
a first conductive layer provided on a side of a first surface of the semiconductor chip, wherein
the first conductive layer includes:
a tin layer; and
a silver layer between the tin layer and the semiconductor chip, and
a film thickness of the silver layer is thinner than a film thickness of the tin layer.

11. The semiconductor device according to claim 10, wherein
the first conductive layer further includes a metal layer,
the metal layer contains at least one of nickel, gold, and palladium, and
a film thickness of the metal layer is equal to or less than the film thickness of the silver layer.
